(19) United States
(12) Patent Application Publication
(10) Pub. No.: US 2023/0258889 A1
(43) Pub. Date: Aug. 17, 2023

(54) OPTICAL DEVICE, BASE, AND BASE MANUFACTURING METHOD

(71) Applicants: Sumitomo Electric Device Innovations, Inc., Yokohama-shi (JP); Sumitomo Electric Industries, Ltd., Osaka-shi (JP)

(72) Inventors: Kazushige OKI, Yokohama-shi (JP); Satoshi YOSHIMURA, Osaka-shi (JP); Kuniyuki ISHII, Yokohama-shi (JP); Masanobu KAWAMURA, Yokohama-shi (JP)

(73) Assignees: Sumitomo Electric Device Innovations, Inc., Yokohama-shi (JP); Sumitomo Electric Industries, Ltd., Osaka-shi (JP)

(21) Appl. No.: 18/009,214

(22) PCT Filed: Jun. 11, 2021
(86) PCT No.: PCT/JP2021/022328

§ 371 Date: Dec. 8, 2022

(30) Foreign Application Priority Data
Jun. 12, 2020 (JP) 2020-102420

(51) Int. Cl. G02B 6/42

(52) U.S. Cl. CPC G02B 6/4257; G02B 6/4281; G02B 6/4204; G02B 6/4237; G02B 6/424; G02B 6/4262

(57) ABSTRACT

An optical device according to one embodiment includes an optical element, a sleeve including a receptacle portion and an insertion portion, and a base having a lower plate having a main surface with the optical element being mounted thereon and a side wall having a hole with the insertion portion of the sleeve optically coupled with the optical element inserted into the hole. A step difference at a position lower than the main surface is formed at a lower position of the hole in the side wall.

### TECHNICAL FIELD

The present disclosure relates to an optical device, a base, and a base manufacturing method. This application is based upon and claims the benefit of priority from Japanese Patent Application No. 2020-102420, filed Jun. 12, 2020, the entire contents of which are incorporated herein by reference.

### BACKGROUND ART

Patent Document 1 describes the receptacle-type optical module. The receptacle-type optical module includes an L-shaped block, a carrier arranged on the L-shaped block, and an optical element mounted on the carrier. A hole is formed in a side wall of the L-shaped block, and a ferrule is passed through the hole. The ferrule holds an optical fiber, and the optical fiber is optically coupled with the optical element. The optical element is mounted on the carrier, and a height of the optical element is adjusted by providing the carrier.

### CITATION LIST

### Patent Literature

Patent Literature 1: Japanese Unexamined Patent Publication No. 2003-107293

### SUMMARY OF INVENTION

An optical device according to one embodiment includes an optical element, a sleeve including a receptacle portion and an insertion portion, and a base having a lower plate having a main surface with the optical element being mounted thereon and a side wall having a hole with the insertion portion of the sleeve optically coupled with the optical element inserted into the hole. A step difference at a position lower than the main surface is formed at the lower position of the hole in the side wall.

A base according to one embodiment includes a lower plate having a main surface and a side wall coupled with the lower plate with a hole having a lower position at a position lower than the main surface being formed. A thickness of the lower plate at the lower position of the hole is smaller than a thickness of the lower plate on the main surface.

A base manufacturing method according to one embodiment, in which a base includes a lower plate having a main surface and a side wall coupled with the lower plate with a hole having a lower position at a position lower than the main surface being formed, and a thickness of the lower plate at the lower position of the hole is smaller than a thickness of the lower plate on the main surface. The manufacturing method includes a process of forming the side wall and the lower plate and a process of forming the hole in the side wall. In the process of forming the hole in the side wall, the hole penetrates the side wall.

### BRIEF DESCRIPTION OF DRAWINGS

FIG. 1 is a perspective view illustrating an optical device according to an embodiment.

FIG. 2 is a cross-sectional view illustrating a base, an optical element, and an optical component of the optical device of FIG. 1.

FIG. 3 is a perspective view illustrating a base, a sleeve, a combiner, a wiring board, a light-emitting element and a light-receiving element of the optical device of FIG. 1.

FIG. 4 is a cross-sectional view illustrating a base, a sleeve, a lens, a combiner, a wiring board, a light-emitting element and a light-receiving element of the optical device of FIG. 1.

FIG. 5 is a perspective view of the sleeve of FIG. 4.

FIG. 6 is a perspective view of the base of FIG. 4.

### DESCRIPTION OF EMBODIMENTS

By the way, there is the increasing demand for miniaturization of optical devices, and thus, miniaturization of each component of the optical devices is required. However, there is a phenomenon that the hole of the L-shaped block described above is provided in the side wall of the L-shaped block, and the position of the hole is high. When the lower plate of the L-shaped block is made thin for miniaturization, there is a possibility that a flatness accuracy of each component mounted on the lower plate of the L-shaped block will deteriorate.

The present disclosure is to provide an optical device, a base, and a base manufacturing method, which can realize miniaturization while maintaining the flatness accuracy of mounted components.

According to the present disclosure, the miniaturization can be achieved while maintaining the flatness accuracy of mounted components.

The contents of the embodiments of the present disclosure are listed and described. An optical device according to one embodiment includes an optical element, a sleeve including a receptacle portion and an insertion portion, and a base having a lower plate having the main surface on which the optical element is mounted and a side wall having a hole with the insertion portion of the sleeve optically coupled with the optical element inserted into the hole. A step difference at a position lower than the main surface is formed at a lower position of the hole in the side wall.

In this optical device, the base has the lower plate and the side wall, and the lower plate has the main surface on which the optical element is mounted. The sleeve has the receptacle portion and the insertion portion inserted into the hole formed in the side wall. The step difference at the position lower than the main surface is formed at a lower position of the hole in the side wall. Therefore, since the lower position of the hole in the side wall is provided at the position lower than the main surface of the lower plate, the miniaturization can be achieved. Since the main surface on which the optical element is mounted is higher than the lower position of the hole, the flatness accuracy of the optical element mounted on the main surface can be ensured. Therefore, the flatness accuracy of the mounted components can be maintained.

The thickness of the lower plate at the lower position of the hole may be smaller than the thickness of the lower plate on the main surface. In this case, since the thickness of the lower plate at the lower position of the hole is small, the base can be made compact, so that the miniaturization can be achieved.

The sleeve is provided with a guide determining a position of the sleeve, and a length from the outer surface of the side wall to the step difference of the lower plate may be larger than a length from the guide to the distal end of the insertion portion. In this case, since the length from the guide determining a position of the sleeve to the distal end of the insertion portion is smaller than the length to the step difference, the guide can abut against the side wall when the sleeve is inserted into the hole in the side wall.

The side surface of the guide may be in contact with the outer surface of the side wall. In this case, when the sleeve is inserted into the side wall, the side surface of the sleeve guide is in contact with the outer surface of the side wall, so that the sleeve can be stably inserted into the hole.

The guide of the sleeve may be fixed to the outer surface by welding. In this case, the fixing of the sleeve to the side wall of the base can be performed firmly by welding.

The base according to one embodiment may include the lower plate having the main surface and the side wall coupled with the lower plate with the hole having the lower position formed at a position lower than the main surface. The thickness of the lower plate at the lower position of the hole may be smaller than the thickness of the lower plate on the main surface. In this case, the lower position of the hole in the side wall is provided at the position lower than the main surface of the lower plate, and since the thickness of the lower plate at the lower position of the hole is small, the base can be made compact, so that the miniaturization can be achieved. Since the lower plate on the main surface on which the optical element is mounted is higher than the lower position of the hole, the flatness accuracy of the optical element can be ensured, so the flatness accuracy of the component can be maintained.

A depth of the hole in the side wall may be determined by a wall of the lower plate, and a length of the depth may be larger than the thickness of the side wall. In this case, since the length of the depth of the hole is larger than the thickness of the side wall, the distal end of the sleeve inserted into the hole can be prevented from abutting against the wall of the lower plate.

In the base manufacturing method according to one embodiment, the base includes the lower plate having the main surface and the side wall coupled with the lower plate with hole having the lower position at a position lower than the main surface being formed. In this base manufacturing method, the thickness of the lower plate at the lower position of the hole is smaller than the thickness of the lower plate on the main surface. The manufacturing method includes a process of forming the side wall and the lower plate and a process of forming the hole in the side wall. In the process of forming the hole in the side wall, the hole penetrates the side wall. In this manufacturing method, the base is manufactured in which the lower position of the hole in the side wall is provided at the position lower than the main surface of the lower plate, and the thickness of the lower plate at the lower position of the hole is smaller than the thickness of the lower plate on the main surface. Therefore, as described above, the miniaturization of the base can be achieved, and the flatness accuracy of the optical element mounted on the main surface can be ensured.

In the process of forming the hole in the side wall, the hole may be formed such that the depth of the hole is larger than the thickness of the side wall. In this case, since the depth of the hole in the side wall is larger than the thickness of the side wall, the distal end of the sleeve inserted into the hole can be prevented from abutting against the wall of the lower plate.

Specific examples of the optical device of the present disclosure will be described below with reference to the drawings. The present invention is not limited to the following examples, but is indicated by the scope of the claims, and the present invention is intended to include all modifications within the scope of the claims and the equivalent scope of the claims. In the description of the drawings, the same or corresponding elements are denoted by the same reference numerals, and redundant descriptions are omitted as appropriate. The drawings may be partially simplified or exaggerated to facilitate the understanding, and the dimensional ratios are not limited to those described in the drawings.

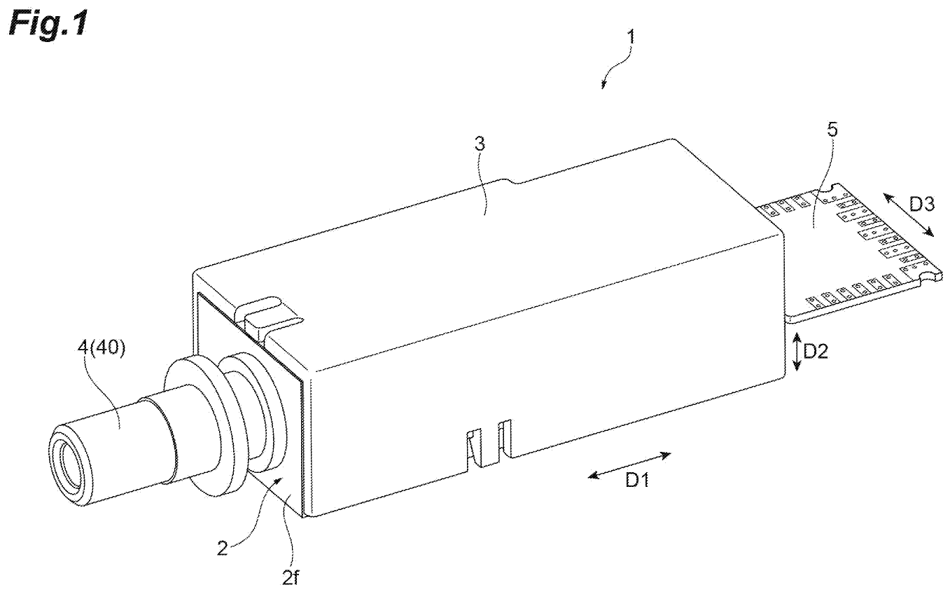

FIG. 1 is a perspective view illustrating an optical device 1 according to this embodiment. As illustrated in FIG. 1, the optical device 1 includes a base 2, a cover 3 covering the base 2, a receptacle 4 having a cylindrical sleeve 40, and a wiring board 5. The optical device 1 extends along a longitudinal direction D1, and the receptacle 4, cover 3 (base 2), and the wiring board 5 are arranged in this order.

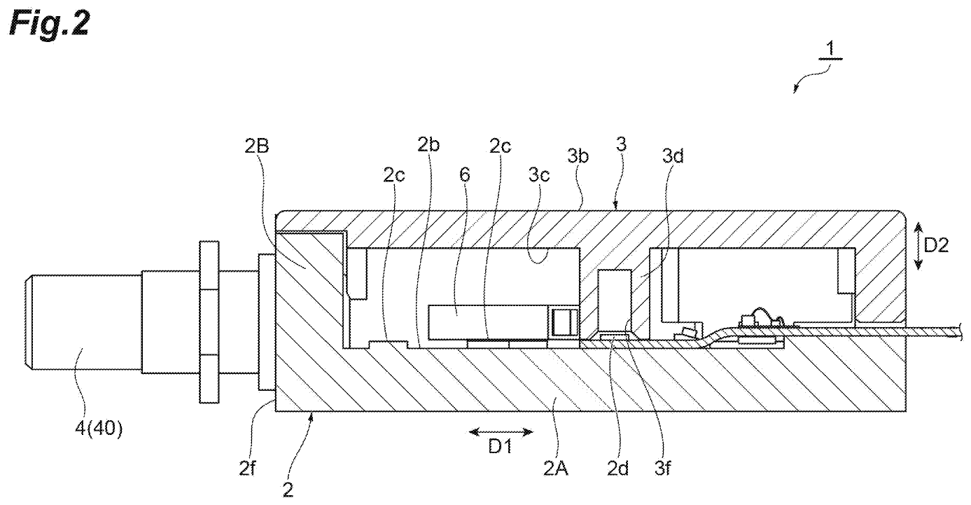

FIG. 2 is a partial cross-sectional view of the optical device 1. As illustrated in FIGS. 1 and 2, the base 2 includes a lower plate 2A extending in the longitudinal direction D1 and a side wall 2B extending in a height direction D2 from one end of the lower plate 2A in the longitudinal direction D1. The base 2 is made of, for example, a metal. The material of the base 2 is, for example, Kovar (an alloy in which at least nickel and cobalt are mixed with iron) or SUS (Steel Use Stainless). The base 2 may be configured with iron, chromium, an alloy of iron and chromium, an alloy of iron and nickel, or plastic.

For example, the base 2 has a rectangular shape as viewed from the height direction D2. The base 2 is a component on which the components housed inside the optical device 1 are mounted. Each part of the optical device 1 is mounted on the lower plate 2A. The lower plate 2A has the long portion protruding from the side wall 2B in the longitudinal direction D1, and each component of the optical device 1 is mounted on the long portion. The lower plate 2A has a main surface 2b facing each component inside the optical device 1, a convex mounting surface 2c on which the components are mounted, a guide pin 2d determining the positions of the cover 3 and the wiring board 5 with respect to the base 2, and an outer surface 2f exposed to the outside of the optical device 1.

The main surface 2b has a rectangular shape extending in the longitudinal direction D1 and a width direction D3. The mounting surface 2c is a portion of the main surface 2b protruding in the height direction D2, and an optical component 6, for example, multiplexing a light is mounted on the mounting surface 2c. The guide pin 2d protrudes from the main surface 2b in the height direction D2. The guide pin 2d has, for example, a cylindrical shape. The guide pin 2d is provided, for example, on one side in the width direction D3 (a position deviated from the center of the base 2 in the width direction D3).

The cover 3 is a component covering the base 2 in the height direction D2, and each component of the optical device 1 is housed inside the base 2 and the cover 3. The cover 3 has an outer surface 3b exposed to the outside of the optical device 1 and an inner surface 3c facing each component of the optical device 1. The inner surface 3c has a protrusion 3d protruding toward the guide pin 2d of the base 2 and a hole 3f formed inside the protrusion 3d with guide pin 2d be fitted thereinto in the height direction D2. By fitting the guide pin 2d into the hole 3f, the cover 3 is fixed to the base 2.

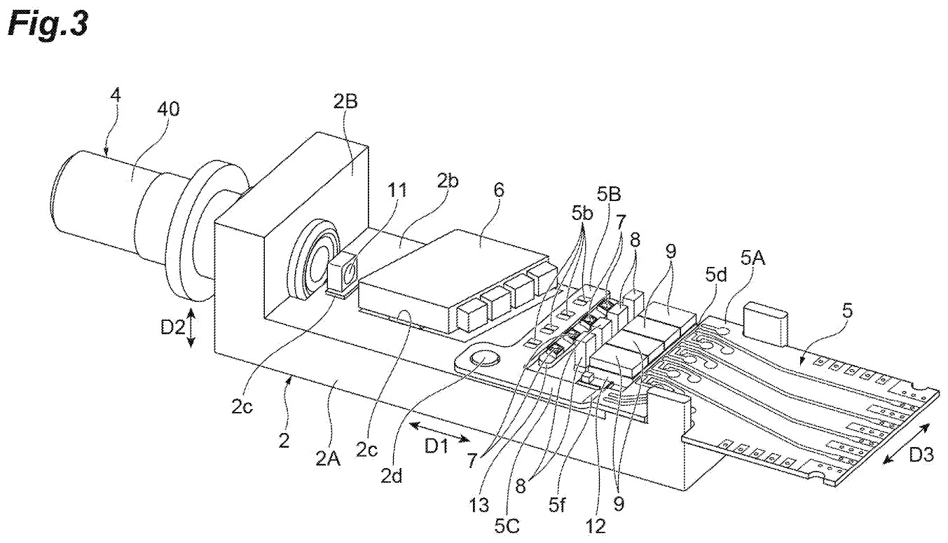

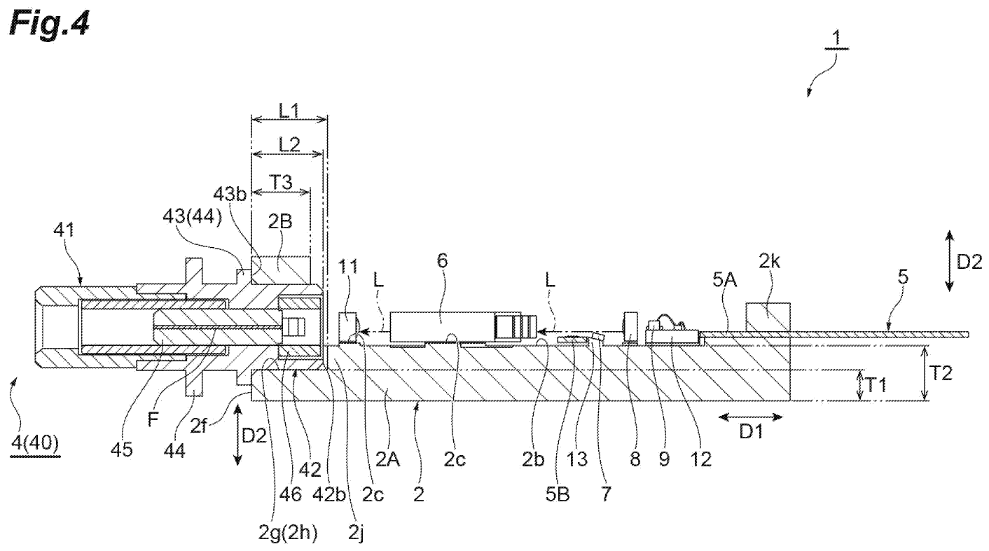

FIG. 3 is a perspective view of the base 2 illustrating a state where the cover 3 is removed from the optical device 1. FIG. 4 is a longitudinal cross-sectional view of the optical device 1 illustrating the state where the cover 3 is removed from the optical device 1. As illustrated in FIGS. 3 and 4, the optical device 1 includes a wiring board 5, an optical component 6 (optical element), a light-receiving element 7 (optical element), a first lens 8 (optical element), a light-emitting element 9 (optical element), and a second lens 11 (optical element) inside the base 2 and the cover 3. A portion of the wiring board 5 extends from the base 2 and the cover 3 to the opposite side of the receptacle 4. A portion of the wiring board 5 extending to the side opposite to the receptacle 4 protrudes outside the optical device 1.

For example, the optical device 1 is a 4-lane multi-channel light-emitting module including the four light-emitting elements 9, the four first lenses 8, the four light-receiving elements 7, the optical component 6, and the second lens 11. The second lens 11 is interposed between the receptacle 4 and the optical component 6. In the optical device 1 having four lanes of optical paths for the output light L, the optical path length of the output light L differs for each channel. The receptacle 4 is arranged, for example, at a position deviated from the center of the base 2 in the width direction D3. The optical path of the output light L from the light-emitting element 9 positioned at the end portion (upper end portion in FIG. 3) opposite to the receptacle 4 in the width direction D3 is the longest. The optical path of the output light L from the light-emitting element 9 positioned at the end portion (lower end portion in FIG. 3) of the receptacle 4 side in the width direction D3 is the shortest.

The plurality of light-emitting elements 9 and the plurality of light-receiving elements 7 are mounted on the base 2. The plurality of light-emitting elements 9 are arranged to be aligned along the width direction D3, and the plurality of light-receiving elements 7 are arranged to be aligned along the width direction D3. For example, each of the four light-emitting elements 9 is mounted on the main surface 2b of the base 2 via a carrier 12. Each light-emitting element 9 is provided corresponding to each of the four first lenses 8 and each of the four light-receiving elements 7. Each light-emitting element 9 is, for example, a semiconductor laser diode (LD), and the output light L which is a divergent light output from the light-emitting element 9 is converted into a collimated light by each first lens 8. Thus, the first lens 8 is optically coupled with the light-emitting element 9.

The wiring board 5 is, for example, an FPC (Flexible Printed Circuit) mounted on the base 2. The wiring board 5 includes a first region 5A extending outward from the optical device 1, a second region 5B provided with pads 5b, and a connection region 5C connecting the first region 5A and the second region 5B to each other. The first region 5A, the second region 5B, and the connection region 5C have a U shape (C shape) as viewed from the height direction D2.

The first region 5A includes pads 5d electrically connected to the light-emitting elements 9. For example, each of the light-emitting elements 9 is electrically connected to the pads 5d via the wire. The first region 5A is provided at the position higher than the second region 5B (a position away from the main surface 2b of the base 2). For example, the height position of the first region 5A substantially matches the height of the carrier 12 on which the light-emitting element 9 is mounted. Accordingly, the wire extending from each light-emitting element 9 to the pads 5d can be decreased.

For example, one wiring board 5 includes the first region 5A as an upper stage and the second region 5B as a lower stage and is fixed to the base 2 by adhesion. The second region 5B is provided at the position lower than the first region 5A, and is in contact with, for example, the main surface 2b of the base 2. Thus, due to the low position of the second region 5B, the wire extending from the wiring board 5 or the light-receiving element 7 can be prevented from interfering with the output light L passing through the light-emitting element 9 and the first lens 8.

The width (the length in the width direction D3) of the connection region 5C of the wiring board 5 is smaller than the width of the first region 5A and the width of the second region 5B. The connection region 5C is provided in the end portion of the receptacle 4 side in, for example, the width direction D3. The connection region 5C extends from the end portion of the first region 5A in the width direction D3 to the end portion of the second region 5B in the width direction D3. A thickness of the wiring board 5 in the first region 5A and a thickness of the wiring board 5 in the second region 5B are, for example, the same. The connection region 5C extends in the longitudinal direction D1 between the first region 5A and the second region 5B and is located at the end portion of the base 2 in, for example, the width direction D3. The connection region 5C has a step or inclination located between the first region 5A and the second region 5B. This embodiment illustrates the example in which the connection region 5C has an inclination 5f.

The output light L output from the light-emitting element 9 via the first lens 8 passes through the light-receiving element 7 and is input to the optical component 6. The optical component 6 is provided between the light-emitting element 9 and the second lens 11 and optically couples the light-emitting element 9 and the second lens 11. Then, the optical component 6 multiplexes the input lights (output lights L) input to the optical component 6. For example, the optical component 6 is an optical multiplexer that multiplexes the four output lights L. The four output lights L are output from the optical component 6 to the second lens 11 as one output light L multiplexed inside the optical component 6. The second lens 11 collects the output light L from the optical component 6, collects the output light L onto the optical fiber held in the receptacle 4, and the output light L passing through the optical fiber held in the receptacle 4 is output to the outside of the optical device 1. The second lens 11 is optically coupled with the light-emitting element 9 via the optical component 6.

The light-receiving element 7 is a monitor PD (Photo Diode) that monitors the output light L from each of the plurality of light-emitting elements 9. The light-receiving element 7 monitors an intensity of the output light L by receiving a portion of the output light L from the light-emitting element 9. For example, each of the four light-receiving elements 7 is mounted on the main surface 2b of the base 2 via a carrier 13 made of a dielectric material. The light-receiving element 7 converts a portion of the output light L from the light-emitting element 9 into an electric signal and outputs the converted electric signal to the pads 5b of the wiring board 5 via a wire (not illustrated). The light-receiving element 7 and the wire extending from the light-receiving element 7 to the pads 5b are provided on a light output side (receptacle 4 side) of the light-emitting element 9. APC control (Auto Power Control) of the output light L from the light-emitting element 9 can be executed by outputting the electric signal from the light-receiving element 7.

The second region 5B is a PD wiring FPC having the pads 5b for wiring to the light-receiving element 7 and is located on the light output side (receptacle 4 side) of the light-receiving element 7. The light-receiving element 7 is a surface incident type light-receiving element.

The light-receiving element 7 is arranged such that a light-receiving surface is oblique to, for example, the optical axis of the output light L. By arranging the light-receiving elements 7 such that the light-receiving surface is oblique to the optical axis of the output light L, the light-receiving elements 7 receive a portion of the output light L.

By arranging the light-receiving element 7 on the light output side of the light-emitting element 9, the output light L can be monitored with a simple configuration on the light output side. The wiring such as wires for the light-receiving element 7 which is a monitor PD is provided on the light output side from the light-receiving element 7. Accordingly, electrical connection to the light-receiving element 7 can be allowed to be performed without decreasing a light receiving sensitivity of the light-receiving element 7. Since the light-receiving element 7 is directly wired to, for example, the pads 5b on the wiring board 5, there is no need to mount a separate carrier or the like. Accordingly, the configuration contributes to cost reduction.

Hereinafter, the base 2 and the receptacle 4 are described in more detail. The shape of the base 2 viewed from the width direction D3 of the optical device 1 is L-shaped. The base 2 is also referred to as an L-shaped base. The side wall 2B of the base 2 is coupled with the lower plate 2A with the hole 2g having a lower position 2h formed at the position lower than the main surface 2b. The receptacle 4 is inserted into the side wall 2B, the hole 2g as the output end of the output light L is formed, and the hole 2g extends in the longitudinal direction D1 at the lower portion of the side wall 2B.

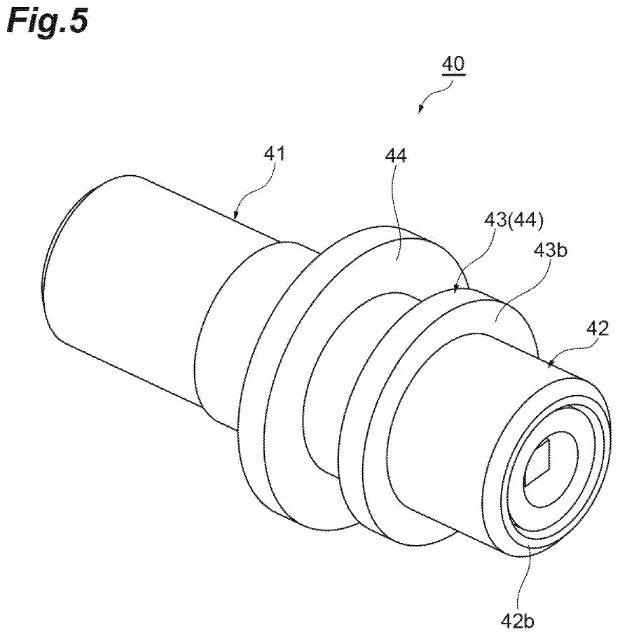

FIG. 5 is a perspective view illustrating the sleeve 40 of the receptacle 4. As illustrated in FIGS. 4 and 5, the receptacle 4 includes, for example, the sleeve 40 having a receptacle portion 41 and an insertion portion 42 inserted into the hole 2g. The hole 2g is formed so that the inner diameter is (slightly) larger than the outer diameter of the insertion portion 42. The sleeve 40 includes, for example, a stub 45 holding an optical fiber F and a lens component 46 optically coupling a light passing through the optical fiber F and optically couples with the second lens 11.

The sleeve 40 is inserted into the hole 2g of the base 2 in the longitudinal direction D1. A step difference 2j at the position lower than the main surface 2b is formed at the lower position 2h of the hole 2g. The step difference 2j (hole 2g) is formed by, for example, counter boring. In this case, for example, the hole 2g is formed later in the side wall 2B by casting or a machine tool (for example, a drill). The lower position 2h of the hole 2g indicates the lower portion of the hole 2g and indicates, for example, a certain region including the lower end of the hole 2g. As an example, the lower position 2h of the hole 2g indicates the portion of the hole 2g lower than the step difference 2j.

For example, a thickness T1 of the lower plate 2A at the lower position 2h of the hole 2g is smaller than a thickness T2 of the lower plate 2A on the main surface 2b. For example, the value of the thickness T1 is 0.5 mm or more and 1.5 mm or less, and is 1.2 mm as an example.

The value of the thickness T2 is, for example, 1.0 mm or more and 3.0 mm or less, and is 2.0 mm as an example. Accordingly, the thickness T2 of the lower plate 2A of the base 2 can be made relatively large. Therefore, high flatness accuracy and structural strength can be maintained, and the position of the optical axis of the output light L in optical element such as the sleeve 40 and the second lens 11 can be lowered. As the result, the height of the side wall 2B in the height direction D2 can be suppressed, and the optical device 1 can be miniaturized.

A length L1 from the outer surface 2f of the side wall 2B to the step difference 2j of the lower plate 2A is larger than a length L2 from a guide 43 determining the position of the sleeve 40 to a distal end 42b of the insertion portion 42. The distal end 42b of the insertion portion 42 is not in contact with the step difference 2j and is separated from the step difference 2j. The guide 43 has a function of preventing the distal end 42b of the insertion portion 42 from being in contact with the step difference 2j. Further, the guide 43 has a function of stabilizing the insertion portion 42 of the sleeve 40 by abutting a side surface 43b against the outer surface 2f.

The depth of the hole 2g (the portion of the hole 2g extending from the outer surface 2f inside the side wall 2B) is determined by a wall of the lower plate 2A, and a length of the depth L1 is larger than a thickness T3 of the side wall 2B. The value of the length L1 is, for example, 1.3 mm or more and 5.2 mm or less, and is 3.0 mm as an example. The value of the thickness T3 is 2.0 mm as an example. The length L2 from the guide 43 to the distal end 42b of the insertion portion 42 is larger than the thickness T3 of the side wall 2B. Accordingly, the insertion portion 42 can be inserted deeper into the hole 2g, which contributes to further miniaturization of the optical device 1. For example, the value of length L2 is 1.2 mm or more and 5.0 mm or less, and is 2.6 mm as an example.

The sleeve 40 has a plurality of flanges 44, and one of the plurality of flanges 44 acts as the guide 43. In a state where the sleeve 40 is fixed to the base 2, for example, the side surface 43b (surface facing the longitudinal direction D1) of the guide 43 is in contact with the outer surface 2f of the side wall 2B. For example, the guide 43 of the sleeve 40 is fixed to the outer surface 2f by welding (YAG welding as an example).

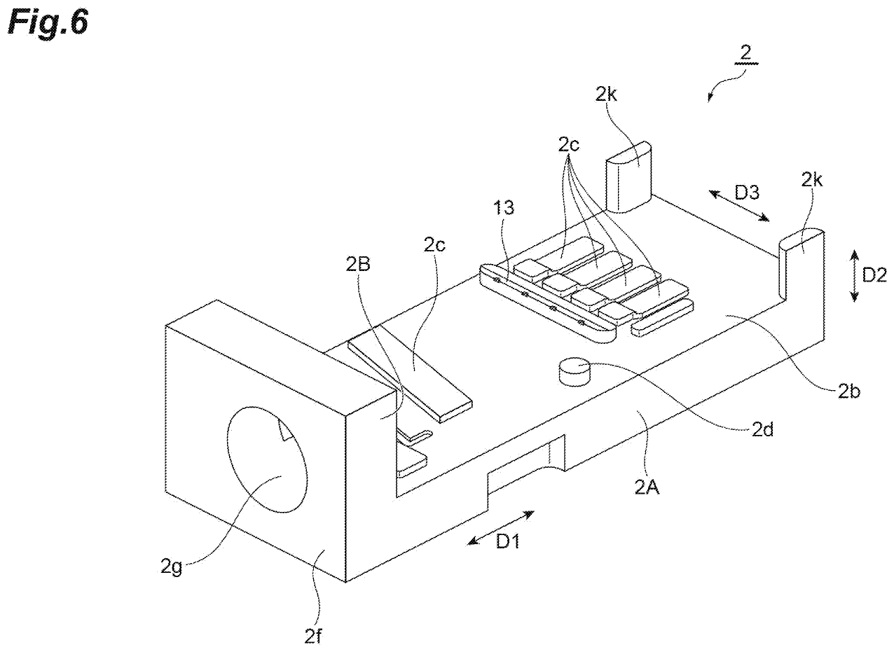

The base manufacturing method according to this embodiment will be described. First, the L-shaped portion configured with the lower plate 2A and the side wall 2B is formed (process of forming the side wall and the lower plate). After forming the lower plate 2A and the side wall 2B, as illustrated in FIGS. 4 and 6, a machine tool (for example, a drill) is applied to the outer surface 2f to form the hole 2g by penetrating the side wall 2B (a process of forming a hole). At this time, the portion of the lower plate 2A (a portion of the side wall 2B side) is scraped off by counter boring to form the hole 2g with the step difference 2j.

Functions and effects obtained from the optical device 1, the base 2, and the base manufacturing method according to the present embodiment will be described. In the optical device 1, the base 2 includes the lower plate 2A and side wall 2B, and the lower plate 2A has the main surface 2b on which optical element such as the second lens 11 is mounted. The sleeve 40 includes the receptacle portion 41 and the insertion portion 42 to be inserted into the hole 2g formed in the side wall 2B. The step difference 2j at the position lower than the main surface 2b is formed at the lower position 2h of the hole 2g in the side wall 2B. Therefore, since the lower position 2h of the hole 2g in the side wall 2B is provided at the position lower than the main surface 2b of the lower plate 2A, the miniaturization can be achieved. Since the main surface 2b on which the optical element such as the second lens 11 are mounted is higher than the lower position 2h of the hole 2g, the flatness accuracy of the optical element mounted on the main surface 2b can be ensured. Therefore, the flatness accuracy of the mounted components can be maintained.

The thickness T1 of the lower plate 2A at the lower position 2h of the hole 2g may be smaller than the thickness T2 of the lower plate 2A on the main surface 2b. In this case, since the thickness T1 of the lower plate 2A at the lower position 2h of the hole 2g is small, the base 2 can be made compact, so that the miniaturization can be realized.

The sleeve 40 may be provided with the guide 43 determining the position of the sleeve 40. The length L1 from the outer surface 2f of the side wall 2B to the step difference 2j of the lower plate 2A may be larger than the length L2 from the guide 43 to the distal end 42b of the insertion portion 42. In this case, since the length L2 from the guide 43 determining the position of the sleeve 40 to the distal end 42b of the insertion portion 42 is smaller than the length L1 to the step difference 2j, when the sleeve 40 is inserted into the hole 2g in the side wall 2B, the guide 43 can be abutted against the side wall 2B.

The side surface 43b of the guide 43 may be in contact with the outer surface 2f of the side wall 2B. In this case, when inserting the sleeve 40 into the side wall 2B, the side surface 43b of the guide 43 of the sleeve 40 is in contact with the outer surface 2f of the side wall 2B. Therefore, the sleeve 40 can be stably inserted into the hole 2g.

The guide 43 of the sleeve 40 may be fixed to the outer surface 2f by welding. In this case, the fixing of the sleeve 40 to the side wall 2B of the base 2 can be performed firmly by welding.

The base 2 may include the lower plate 2A having the main surface 2b and the side wall 2B coupled with the lower plate 2A with the hole 2g having the lower position 2h at the position lower than the main surface 2b being formed. The thickness T1 of the lower plate 2A at the lower position 2h of the hole 2g is smaller than the thickness T2 of the lower plate 2A on the main surface 2b. Therefore, the lower position 2h of the hole 2g in the side wall 2B is provided at the position lower than the main surface 2b of the lower plate 2A, and the thickness T1 of the lower plate 2A at the lower position 2h of the hole 2g is small, so that the base 2 can be made compact, and the miniaturization can be realized. Since the lower plate 2A on the main surface 2b on which the optical element is mounted is higher than the lower position 2h of the hole 2g, the flatness accuracy of the optical element can be ensured, so that the flatness accuracy of the component can be maintained.

The depth of the hole 2g in the side wall 2B is determined by a wall (step difference 2j) of the lower plate 2A, and a length of the depth L1 may be larger than the thickness T3 of the side wall 2B. In this case, since the length of the depth L1 of the hole 2g is larger than the thickness T3 of the side wall 2B, the distal end 42b of the sleeve 40 inserted into the hole 2g can be prevented from abutting against the wall of the lower plate 2A.

The base manufacturing method according to the present embodiment includes a process of forming the side wall 2B and the lower plate 2A and a process of forming the hole 2g in the side wall 2B, and in the process of forming the hole 2g in the side wall 2B, the hole 2g penetrates the side wall 2B. In this manufacturing method, the lower position 2h of the hole 2g in the side wall 2B is provided at the position lower than the main surface 2b of the lower plate 2A, and the base 2 where the thickness T1 of the lower plate 2A at the lower position 2h of the hole 2g is smaller than the thickness T2 of the lower plate 2A on the main surface 2b is produced. Therefore, as described above, the miniaturization of the base 2 can be achieved, and the flatness accuracy of the optical element mounted on the main surface 2b can be ensured.

In the process of forming the hole 2g in the side wall 2B, the hole 2g may be formed such that the depth L1 of the hole 2g is larger than the thickness T3 of the side wall 2B. In this case, since the depth L1 of the hole 2g in the side wall 2B is larger than the thickness T3 of the side wall 2B, the distal end 42b of the sleeve 40 inserted into the hole 2g is prevented from abutting against the wall of the lower plate 2A.

The base 2 has a protrusion 2k protruding upward at the end portion opposite to the side wall 2B in the longitudinal direction D1. For example, the base 2 includes a pair of protrusions 2k aligned in the width direction D3. Therefore, for example, as shown in FIG. 4, even if the base 2 on which the mounted components are erroneously placed upside down, the side wall 2B and the protrusion 2k hit the floor or the like, so that the mounted components can be prevented from interfering with the floor or the like.

Heretofore, the embodiments of the optical device according to the present disclosure have been described above. However, the invention is not limited to the embodiments described above. That is, it will be readily recognized by those skilled in the art that the present invention can be modified and changed in various ways without departing from the scope of the claims. For example, the shape, size, number, material, and layout of each component of the optical device are not limited to those described above and can be changed as appropriate.

For example, in the above-described embodiments, the optical device 1 which is an optical transmitter is exemplified. However, the optical device according to the present disclosure may be an optical device other than the optical transmitter and may be an optical receiver. In the above-described embodiments, the optical component 6, which is an optical multiplexer is exemplified. However, the optical component may be an optical component other than the optical multiplexer, and may be, for example, an optical demultiplexer demultiplexing input lights. In this manner, the types of the optical device and the components mounted on the optical device can also be changed as appropriate.

### REFERENCE SIGNS LIST

1: optical device, 2: base, 2A: lower plate, 2B: side wall, 2b: main surface, 2c: mounting surface, 2d: guide pin, 2f: outer surface, 2g: hole, 2h: lower position, 2j: step differences, 2k: protrusion, 3: cover, 3b: outer surface, 3c: inner surface, 3d: convex portion, 3f: hole, 4: receptacle, 5: wiring board, 5A: first region, 5b, 5d: pads, 5B: second region, 5C: connection region, 5f: inclination, 6: optical component (optical element), 7: light-receiving element (optical element), 8: first lens (optical element), 9: light-emitting element (optical element), 11: second lens (optical element), 12, 13: carrier, 40: sleeve, 41 receptacle portion, 42: insertion portion, 42b: distal end, 43: guide, 43b: side surface, 44: flange, 45: stub, 46: lens component, D1: longitudinal direction, D2: height direction, D3: width direction, F: optical fiber, L: output light.

1.-9. (canceled)

10. An optical device comprising:
an optical element;
a sleeve including a receptacle portion and an insertion portion;
a base having a lower plate having a main surface with the optical element being mounted thereon and a side wall having a hole with the insertion portion of the sleeve optically coupled with the optical element inserted into the hole, the side wall being integral with the lower plate,
wherein a step difference is provided at a boundary between the hole and the lower plate, wherein an inner lower surface of the hole in the side wall of the base is positioned lower than the lowermost portion of the main surface of the lower plate of the base.

11. The optical device according to claim 10, wherein a thickness of the lower plate on the inner lower surface of the hole is smaller than a thickness of the lower plate on the lowermost part of the main surface.

12. The optical device according to claim 10,
wherein the sleeve is provided with a guide determining a position of the sleeve, and
wherein a length from the outer surface of the side wall to the step difference of the lower plate is larger than a length from the guide to a distal end of the insertion portion.

13. The optical device according to claim 12, wherein a side surface of the guide is in contact with the outer surface of the side wall.

14. The optical device according to claim 13, wherein the guide of the sleeve is fixed to the outer surface by welding.

15. A base comprising:
a lower plate having a main surface; and
a side wall coupled with the lower plate with the hole having an inner lower surface formed at the position lower than the lowermost portion of the main surface of the lower plate,
wherein a thickness of the lower plate at the lower surface of the hole is smaller than a thickness of the lower plate at the lowermost portion of the main surface.

16. The base according to claim 15, wherein a depth of the hole in the side wall is determined by a wall of the lower plate, and a length of the depth is larger than a thickness of the side wall.

17. A base manufacturing method, a base including:
a lower plate having a main surface; and
a side wall coupled with the lower plate with a hole having an inner lower surface formed at a position lower than a lowermost portion of the main surface of the lower plate,
wherein a thickness of the lower plate on the lower surface of the hole is smaller than a thickness of the lower plate on the lowermost portion of the main surface, the base manufacturing method comprising:
a process of forming the side wall and the lower plate; and
a process of forming the hole in the side wall,
wherein, in the process of forming the hole in the side wall, the hole penetrates the side wall.

18. The base manufacturing method according to claim 17, wherein, in the process of forming the hole in the side wall, the hole is formed such that a length of the depth of the hole is larger than a thickness of the side wall.
